(19) United States
(12) Patent Application Publication
(10) Pub. No.: US 2016/0081458 A1
(43) Pub. Date: Mar. 24, 2016

(54) BARBER CLIPPER STAND

(71) Applicants: Christopher Dean Sullivan, Pittsburgh, PA (US); Richard Earl Harris, Pittsburgh, PA (US)

(72) Inventors: Christopher Dean Sullivan, Pittsburgh, PA (US); Richard Earl Harris, Pittsburgh, PA (US)

(21) Appl. No.: 14/859,380

(22) Filed: Sep. 21, 2015

Related U.S. Application Data
(60) Provisional application No. 62/054,104, filed on Sep. 23, 2014.

(51) Int. Cl. A45D 44/06; H05K 5/02; A47L 7/00; F16M 11/04

(52) U.S. Cl. CPC A45D 44/06; F16M 11/04; H05K 5/0247; A47L 7/0066

(57) ABSTRACT

An apparatus for holding and separating the electrical power cords of multiple barber clippers and other barber accessories. The apparatus includes a central pole, at least one hanger attachment holder attached to the central pole and at least one cord separator attached to the central pole. The hanger attachment holder has at least two hangers attached to the underside or perimeter of the hanger shelf for holding barber clippers and other barber accessories. The cord separator is located under the hanger attachment holder, and has at least two cutouts along the perimeter of the shelf, with each cutout aligned with the position of a corresponding hanger on the hanger shelf and acting to gather the electrical power cord of a barber clipper or other barber accessory held by the hanger.

### CROSS-REFERENCE TO RELATED APPLICATION

This application claims the benefit under 35 U.S.C. §119 of U.S. Provisional Application Ser. No. 62/054,104, filed Sep. 23, 2014, which is incorporated herein by reference.

### FIELD OF THE INVENTION

The present invention is related generally to a barber clipper stand for use in holding two or more barber clippers and separating the electrical wires for each.

### BACKGROUND OF THE INVENTION

The present invention addresses a current problem in many barber shops. Specifically, barbers use multiple clippers to service customers, and the clippers are often plugged into multiple outlets or a single power jack such that the cords for the clippers lay over each other on the floor. This arrangement presents safety and tripping hazards within a barber shop. It also reduces the tangling of power cords general and promotes the efficiency of barber shop operations through general cord management.

The present invention provides a barber clipper stand that holds two or more barber clippers and helps separate the power cords for each. As such, the safety and tripping hazards associated with many current operations are obviated.

### BRIEF DESCRIPTION OF THE DRAWINGS

The present invention is illustratively shown and described in reference to the accompanying drawings, in which:

FIG. 1 is an isometric view of one embodiment of the barber clipper stand of the present invention.

FIG. 2 is an isometric view of the embodiment of the present invention shown in FIG. 1, with three barber clippers attached to the stand.

FIG. 3 is a front view of the embodiment of the barber clipper stand shown in FIG. 1.

FIG. 4 is a back view of the embodiment of the barber clipper stand shown in FIG. 1.

FIG. 5 is an isometric view of the top portion of the embodiment of the barber clipper stand shown in FIG. 1.

FIG. 6 is an isometric view of the cord separator in the embodiment of the barber clipper stand shown in FIG. 1.

FIG. 7 is a top view of an alternative embodiment of the cord separator in the embodiment of the barber clipper stand shown in FIG. 1, with a modified number of cut-outs.

FIG. 8 is a top view of a further alternative embodiment of the cord separator in the embodiment of the barber clipper stand shown in FIG. 1, with a further modified shape and number of cut-outs.

FIG. 9 is a top view of a further alternative embodiment of the cord separator in the embodiment of the barber clipper stand shown in FIG. 1, with a further modified shape and number of cut-outs.

FIG. 9 is an isometric view of the embodiment of the barber clipper stand shown in FIG. 1, with a vacuum attachment.

### DETAILED DESCRIPTION OF THE INVENTION

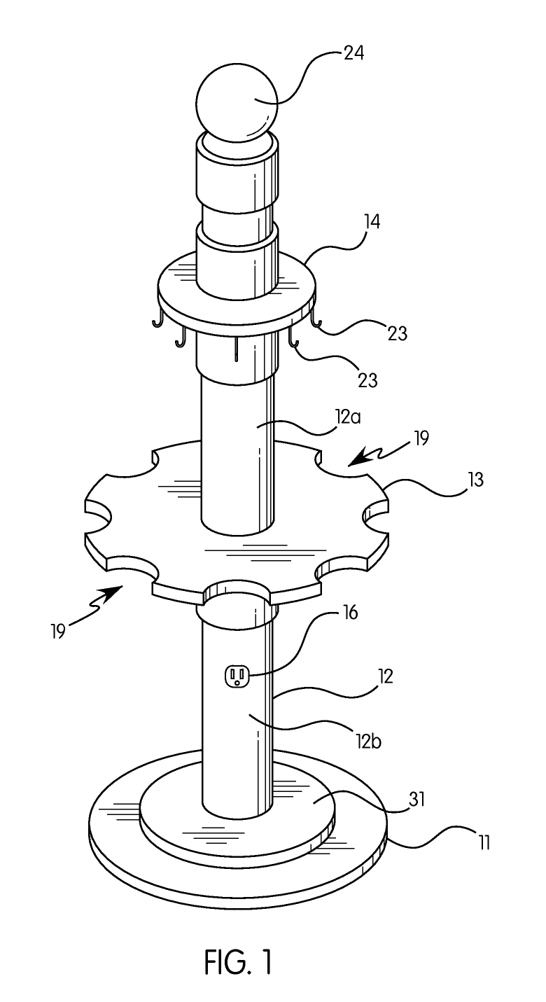

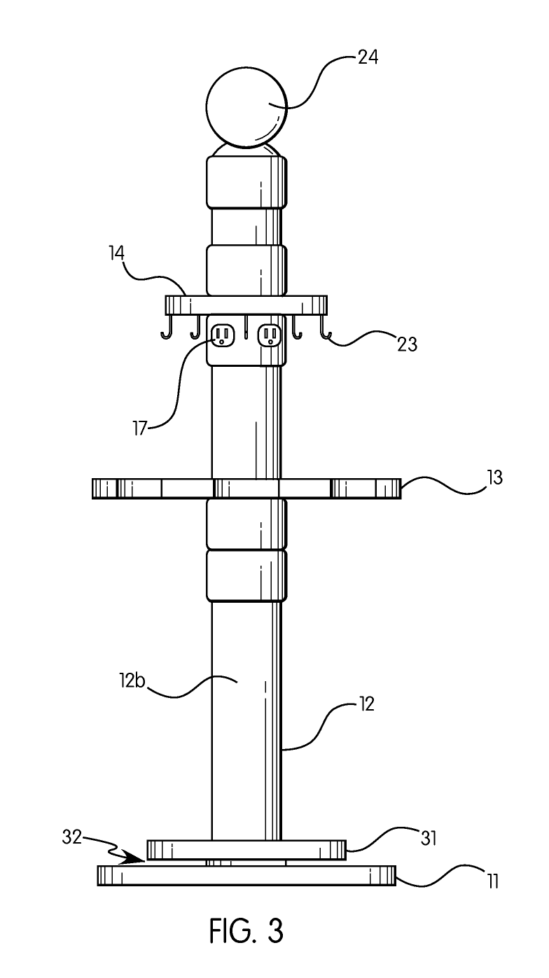

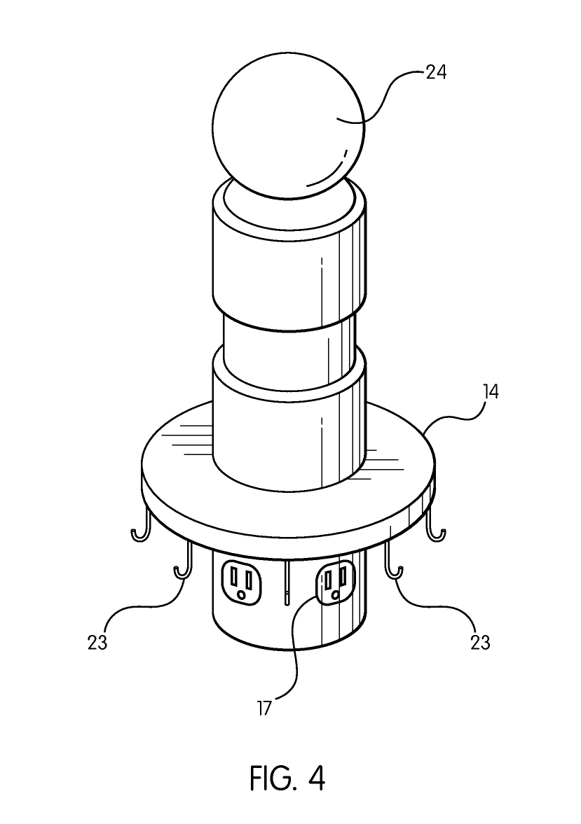

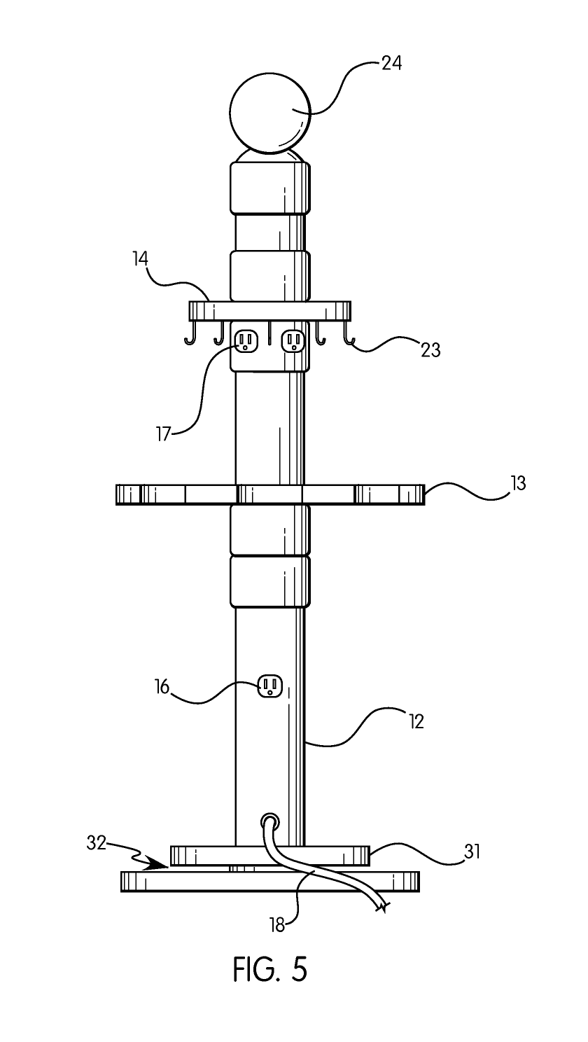

Referring to FIGS. 1-6, the barber clipper stand 10 of the present invention, in one embodiment, includes a base 11, a central pole 12, at least one cord separator 13 and at least one hanger attachment holder 14. Barber clipper stand 10 can also include, in alternative embodiments, at least one electrical outlet 16 located at the lower portion of pole 12 under cord separator 13. In addition, at least one electrical outlet 17 can be located under clipper attachment holder 14. Barber clipper holder 10, in turn, can be connected to an electrical outlet by electrical cord 18. Other power supplies may be used with barber clipper stand 10, such as a battery. In an alternative embodiment of the invention, a raised ledge 31 sits above base 11 to form recess 32. Recess 32 can be used to store cord 18 when not in use (cord 18 can be wrapped around pole 12 and inside recess 32. Ledge 31 can have varying perimeter shapes.

In a preferred embodiment, electrical cord 18 provides power to all electrical outlets and devices associated with barber clipper stand 10, including electrical outlets 16 and 17, as well as light 24. Additional electrical outlets can also be added to pole 12 of barber clipper stand 10, such as outlets located just above cord separator 13. In an alternative embodiment, at least one USB port can be added to pole 12 as well. This port is preferably located above cord separator 13 and below holder 14 so that the barber or customer can charge a cellular or smart phone, or similar electronic device such as a tablet, while the device is resting on top of cord separator 13. Charging can occur while the barber is servicing the customer. Ports 12 can also be placed at other locations along pole 12. In a further embodiment, pole 12 can also include at least one electrical switch 15 that activates the power to all or a portion of the outlets, ports and lights associated with barber clipper stand 10. Preferably, this electrical or power switch 15 is located below cord separator 13, but one or more other locations are possible.

In yet another embodiment as shown in FIG. 10, a vacuum accessory 40 can be attached near base 11 of pole 12. The vacuum accessory 40 is electrically connected to the power source for barber clipper stand 10. In use, cut hair can be swept toward the vacuum accessory 40, which can then be activated to vacuum the cut hair. The suction vent in the vacuum accessory can be a fixed vent 41 or attached to a hose (not shown). Vacuum accessory 40 can have a waste receptacle and access to same consistent with standard vacuum devices, and the configuration and placement of vacuum accessory 40 at the base 11 of pole 12 can vary.

Base 11 can be constructed of any rigid material and can have varying shapes. In FIGS. 1-6, base 11 has a circular perimeter shape. However, other geometric shapes can also be used, so long as base 11 provides stability and support to the barber clipper stand 10.

Similarly, central pole 12 is shown as having a circular cross section; however, other cross sectional shapes can be used. Pole 12 is also constructed of a rigid material. In a preferred embodiment, pole 12 is hollow, and the internal cavity of pole 12 is used to house power cords that run to various outlets 16 and 17, as well as light 24.

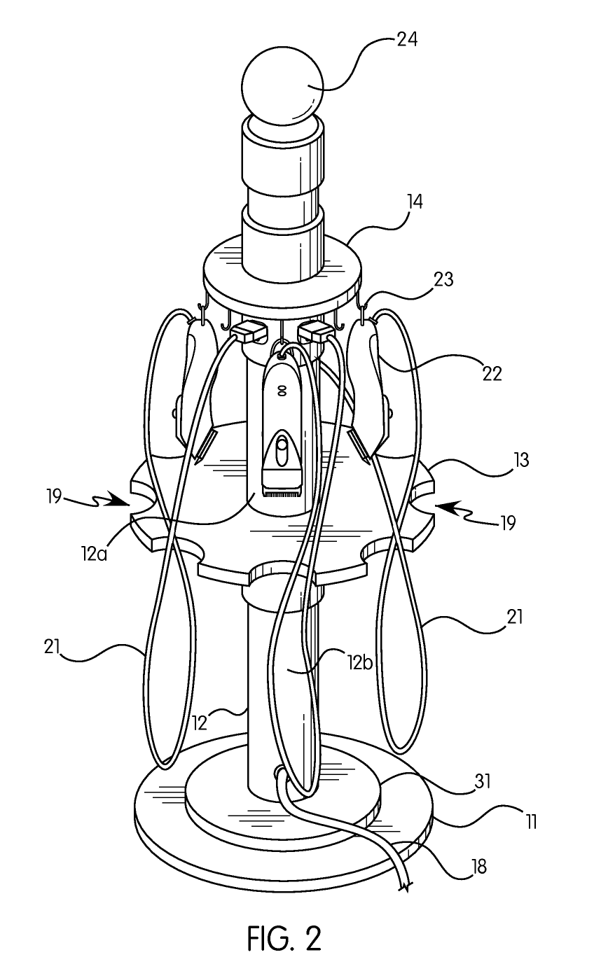

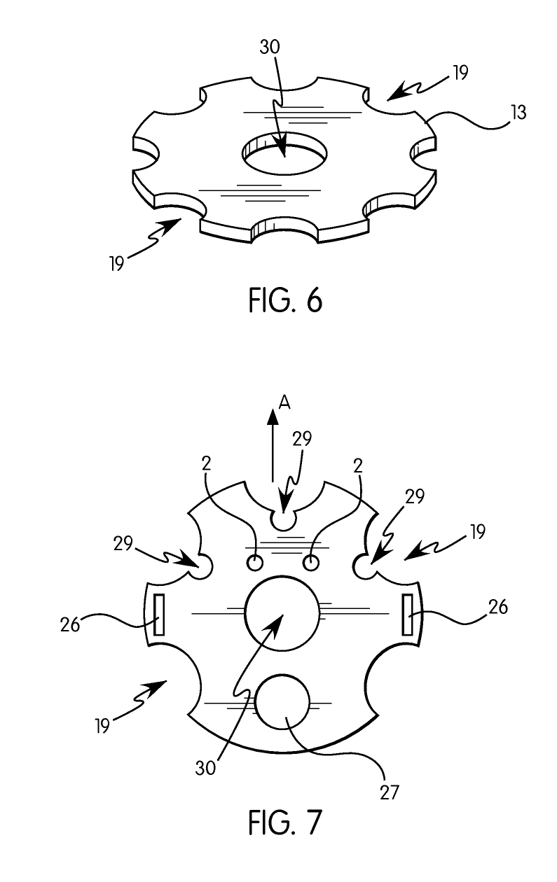

Cord separator 13 is located approximately in the middle of the vertical length of pole 12. Cord separator 13 has a flat plane, in a preferred embodiment, which is substantially perpendicular to the vertical access of pole 12. Cord separator has a central opening 30, through which pole 12 passes. In other embodiments, cord separator 13 can be angled and have an uneven surface. In a preferred embodiment, cord separator 13 has a circular or ovoid perimeter, but other geometric shapes, again, can be used. As shown in FIGS. 1 and 6, cord separator 13 has at least two cutouts 19 along the perimeter of cord separator 13. As shown in FIG. 2, these cutouts 19 are arranged to hold, separate, and manage the electrical cords 21 associated with each barber clipper 22. Cutouts 19 can have various shapes, including semi-circles, wedges and rectangles. As further shown in FIG. 7, each cutout 19, can have an additional, smaller cutout 29, which is used to hold the relatively stationary suspended cord that that is connected to outlet 17. Cord separator 13 has a sufficient height to suspend the full length of cords 21. Typically, a cord 21 for a clipper 22 is eight (8) feet in length. As such, cord separator 13 would need to be at least four (4) feet or forty-eight (48) inches from the base 11.

In an alternative embodiment, as shown in FIG. 7, cord separator 13, with front A, has a modified number (5) of cutouts 19, and can have internal cut-outs as well. These cut-outs can include small circular holes 27 near pole 12 that can be used to pass a recharging or other electrical cord from the upper surface of cord separator 13 to the area below the cord separator 13. More directly, a cellular or smart phone or other device can be placed on cord separator 13 and a charging cord can be run from the phone or other device, through the circular cut-out, to an electrical outlet in pole 12 located below cord separator 13. To aid in holding such devices and other items on cord separator 13, raised edges or barriers 26 can be included on the top surface of cord separator 13. The edges or barriers 26 prevent items on the surface from sliding off of the surface. Larger cut-outs 28 can be made in cord separator 13 to act as receiving areas for other devices, such a blow dryer 25.

Hanger holder 14 is located above cord separator 13. Hanger holder 14, in a preferred embodiment, also has a flat plane that is substantially perpendicular to the vertical access of pole 12. In alternative embodiments, however, hanger holder 14 can be angled and have an uneven surface. Hanger holder 14, in a preferred embodiment, can have a circular or ovoid perimeter, but other geometric shapes are possible. Hanger holder 14 has individual hangers 23 located along the underside or outer perimeter of hanger holder 14. Hangers 23 are used to hold barber clippers 22, with hangers 23 being arranged to correspond to the location of cutouts 19 below.

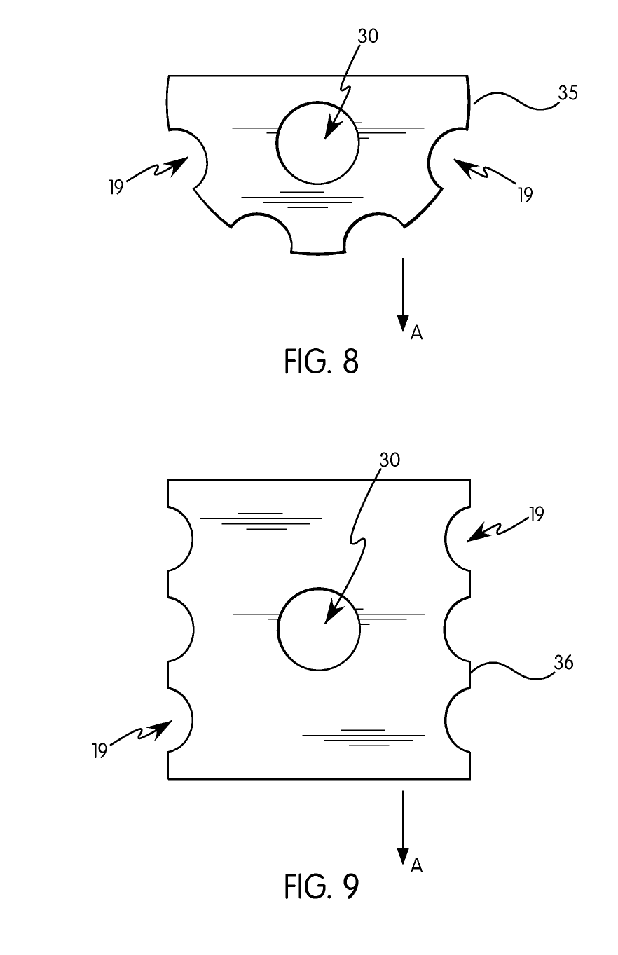

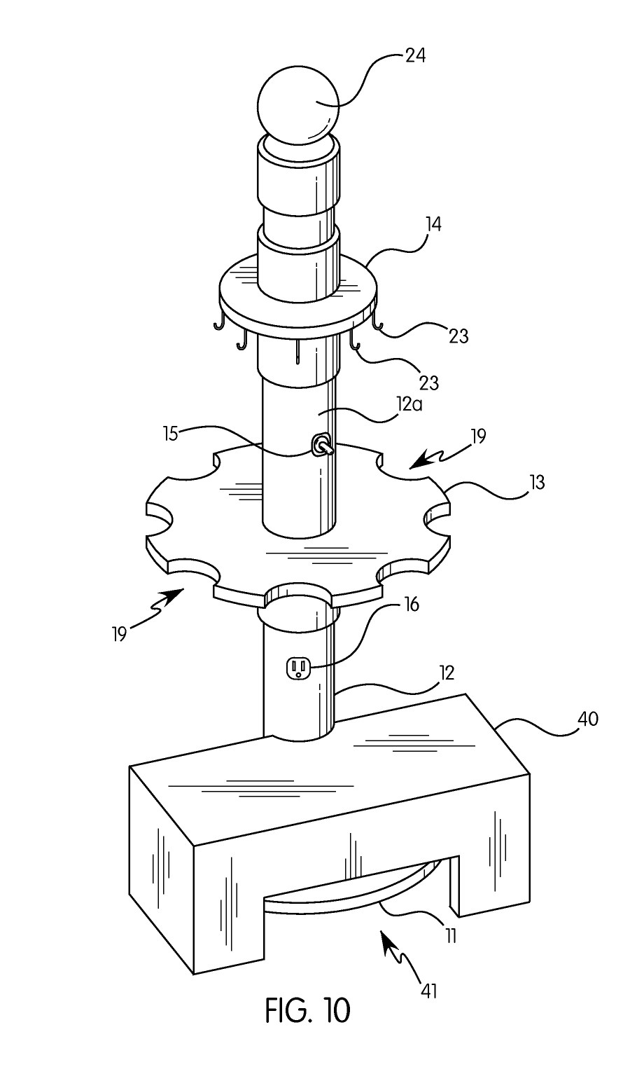

FIGS. 8 and 9 show other embodiments of the cord separator. In particular, FIG. 8, with front A, shows cord separator 35 with a flat edge that would be disposed to the rear of pole 12. Cord separator has a central opening 30 and cutouts 19 arranged toward the front or operator side of pole 12 and stand 10. The number and position of cutouts 19 in cord separator 35 can vary. In this embodiment, the hanger holder 14 would have a corresponding shape and orientation of hangers 23. This orientation of the cutouts 19 in cord separator 35 assists in holding barber clippers 22 toward the front of barber clipper stand 10. FIG. 9, with front A, shows yet another embodiment of cord separator 36, again with a central opening 30 and cutouts 19 situated on the sides of cord separator 35. This assists in allowing one barber clipper stand 10 to be used be two operators—each hanging their respective barber clippers on a respective side of stand 10. The hanger holder 14 and hangers 23 would have a corresponding orientation.

In yet another embodiment, barber clipper stand 10 can be wall-mounted, such that stand 10 does not have a base 11.

The present invention can also have other shelves or ledges that attach to and/or encompass pole 12. These shelves and ledges can be placed at various locations along pole 12 and can be used to hold other items and accessories used for barber shop or hair dresser/cosmetology operations. These shelves and ledges can have internal cut-outs, hangers and/or holder attachments along the perimeter to assist in holding various accessories and items.

In a further alternative embodiment of barber clipper stand 10, a light 24 can be located at the top of pole 12. Light 24 can have any shape or size and can, for example, can be a globe light similar to the light at the top of a barber light. A lighted barber pole can also be incorporated into barber clipper stand 10. Light 24 can be activated when cord 18 is plugged in and/or by a separate switch associated with pole 12.

Cord separator 13 can also be used to support additional barber accessories, such as hair dryer 25 as shown in FIG. 1. More specifically, cord separator 13 can also have hangers 23 attached to the underside or outer perimeter of cord separator 13. Hair dryer 25 can be plugged into electrical outlet 16. Barber clippers 22, in a preferred embodiment, plug into electrical outlet 17.

In a further embodiment of barber clipper stand 10, the invention can be disassembled for travel and setup in various locations. More specifically, by way of one example, the lower section 12b of pole 12 can separate from the upper section 12a of pole 12. In addition, a carry handle can be attached to either or both of pole sections 12a and 12b. In connection with such disassembly, the power supply from cord 18 also is separated between sections 12a and 12b. This can be done internally or externally to pole 12.

In view of the above, it will be seen that the several objections of the invention are achieved and other advantageous results obtained. As various changes could be made in the above device without departing from the scope of the invention, it is intended that all matter contained in the above description or shown in the accompanying drawings shall be interpretive as illustrative and not in a limiting sense.

What is claimed is:

1. An apparatus for holding and separating the electrical power cords of multiple barber clippers and other barber accessories, the apparatus comprising:
a central pole;
at least one hanger attachment holder attached to the central pole, the at least one hanger attachment holder comprised of a substantially flat hanger shelf and at least two hangers attached to the underside or perimeter of the hanger shelf for holding barber clippers and other barber accessories; and
at least one cord separator attached to the central pole and located under the at least one hanger attachment holder, the at least one cord separator comprised of a substantially flat separator shelf with at least two cutouts along the perimeter of the shelf, each cutout aligned with the position of a corresponding hanger on the hanger shelf and acting to gather the electrical power cord of a barber clipper or other barber accessory held by the hanger.

2. The apparatus of claim 1, wherein the apparatus further comprises a base.

3. The apparatus of claim 1, wherein the apparatus is wall-mounted.

4. The apparatus of claim 1, wherein the apparatus further comprises at least on electrical outlet located in the central pole and a power supply.

5. The apparatus of claim 4, wherein the central pole is hollow and the power supply is located inside the central pole.

6. The apparatus of claim 1, wherein the apparatus further comprises at least one USB port.

7. The apparatus of claim 1, wherein the apparatus further comprises a vacuum accessory attached to the central pole.

8. The apparatus of claim 1, wherein the apparatus further comprises a light attached to the top of the central pole.

9. The apparatus of claim 1, wherein the apparatus is portable.

10. The apparatus of claim 9, where the central pole is sectional and can be disassembled and assembled.

11. The apparatus of claim 9, where the central pole includes a carry handle attached to the central pole.

12. The apparatus of claim 1, wherein the at least one hanger shelf has internal cutouts to aid in holding barber accessories by insertion into the cutouts.

13. The apparatus of claim 1, wherein the at least one separator shelf has internal cutouts to aid in holding barber accessories by insertion into the cutouts.

14. The apparatus of claim 1, wherein the at least one hanger shelf has raised edges along the perimeter of the at least one hanger shelf to assist in preventing accessories placed on the at least one hanger shelf from sliding off of the at least one hanger shelf.

15. The apparatus of claim 1, wherein the at least one separator shelf has raised edges along the perimeter of the at least one separator shelf to assist in preventing accessories placed on the at least one separator shelf from sliding off of the at least one separator shelf.

16. The apparatus of claim 1, wherein additional shelves are attached to either or both of the at least one hanger shelf and at least one separator shelf.
